(19) United States
(12) Patent Application Publication
(10) Pub. No.: US 2004/0042545 A1
(43) Pub. Date: Mar. 4, 2004

(54) Equalizer of single carrier receiver for improving equalization speed and equalization method thereof

(75) Inventors: Dong-seog Han, Daegu-city (KR); Hae-sock Oh, Daegu-city (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-City (KR)

(21) Appl. No.: 10/602,638

(22) Filed: Jun. 25, 2003

(30) Foreign Application Priority Data
Aug. 28, 2002 (KR) 2002-51060

(51) Int. Cl. H03K 5/159; H03H 7/30; H03H 7/40

(52) U.S. Cl. 375/232

(57) ABSTRACT

The present invention provides an equalizer capable of improving an equalization speed. The equalizer comprises a channel estimation unit estimating channel estimation values using a received signal inputted thereto and a generated field synchronizing signal, a filter filtering a pre-ghost and post-ghost of the received signal using the channel estimation values, wherein the filter initializes coefficients of filters thereof and updates the coefficients gradually, thereby filtering the pre and post-ghosts and an error calculation unit calculating an equalization error using an output signal from the filter unit. The filter updates the coefficients of the filters according to the equalization error and filters the pre and post-ghosts through these updated filters. The filters of the equalizer are initialized by estimating a delay profile of a received signal, thereby improving a convergence speed of equalization of an equalizer.

### CROSS-REFERENCE TO RELATED APPLICATIONS

This application claims the benefit of Korean Application No. 2002-51060, filed Aug. 28, 2002, in the Korean Intellectual Property Office, the disclosure of which is incorporated herein by reference.

### BACKGROUND OF THE INVENTION

1. Field of the Invention

The present invention relates to an equalizer employing a single carrier mode, and more particularly, to an equalizer capable of improving a convergence speed thereof.

2. Background of the Related Art

FIG. 1 is a schematic block diagram of a conventional single carrier receiver capable of receiving a broadcasting signal transmitted in a general single carrier mode.

The single carrier receiver comprises an RF (Radio Frequency) unit 10, an ADC (Analog to Digital Converter) 20, a synchronizer 30, an equalizer 40, a decoder 50 and a field synchronizing signal generator 60. The RF unit 10 tunes a broadcasting signal received by an antenna 11 from a single carrier transmitter and converts a tuned band of the signal to a base band signal. The ADC 20 converts the received signal in an analog format to a digital signal by a digital sampling process. The synchronizer 30 compensates frequency, phase and timing offsets for an input signal. The equalizer 40 compensates a channel distortion on a transmission channel for the signal of which the offsets are compensated as above. The field synchronizing signal generator 60 generates a field synchronizing signal, which is a reference signal established between a transmitter and receiver, thereby providing the generated signal to the equalizer 40. The field equalizer 40 compensates a channel distortion based on the field synchronizing signal from the field synchronizing signal generator 60. The decoder 50 decodes data from the signal equalized by the equalizer 40.

The single carrier receiver may include a linear equalizer or a decision feedback equalizer. The operation of each of the equalizers will hereinafter be described in reference to FIGS. 2 and 3.

FIG. 2 is a block diagram of a linear equalizer. The linear equalizer 40 comprises a filter 42 having an FIR type filter, a delay unit 49 and a switching unit 45 for switching in response to an operation mode of the equalizer. Calculating the equalization error to update the filter coefficients is an iterative process beginning with initialized filter coefficients. There are two modes of operation of the equalizer, one is a blind mode in which a received signal is used for equalization and the other is a training mode in which a field synchronizing signal, which is information synchronizing a transmitter and receiver, is used for equalization.

In the blind mode, the switching unit 45 is connected to a point a for an equalization error to be calculated. The equalization error is calculated by using an output signal from the filter 42 and a signal of a predetermined level outputted from the decision unit 46 through the filter 42.

In the training mode, the switching unit 45 is connected to a point b so that an equalization error is calculated. The equalization error is calculated by using an output signal from the filter 42 and a field synchronizing signal delayed for a predetermined period of time by the delay unit 49. The delay time is the same as a delay time of a main signal of a highest level among received signals.

As described above, the coefficients of the filter 42 are updated using the equalization error calculated in each operation mode to remove multi-path of the received signal.

FIG. 3 is a block diagram of a decision feedback equalizer. The decision feedback equalizer comprises an FF (Feed Forward) unit 342, an FB (Feed Back) unit 43, a first adder 44, a switching unit 45, a decision unit 46, a second adder 47 and a delay unit 49. The FF unit 342 includes an FIR (Finite Impulse Response) type filter to remove a pre-ghost, which is a multi-path signal received before reception of a main signal. The FB unit 43 includes an IIR (Infinite Impulse Response) type filter to remove a post-ghost, which is a multi-path signal received after reception of a main signal. A process of calculating an equalization error in response to an operation mode selected by the switching unit 45 and updating coefficients of the filter in the FF Unit 42, is repeated for equalization.

In the blind mode, the first adder 44 adds output signals from the FF unit 42 and the FB unit 43, and the decision unit 46 decides a signal level for an output signal from the first adder 44. The switching unit 45 is connected to a point a for an equalization error to be calculated. The second adder 47 calculates the equalization error by adding output signals from the first adder 44 and the decision unit 46.

In the training mode, the switching unit 45 is connected to a point b and the first adder 44 adds the output signals from the FF unit 42 and the FB unit 43. The second adder 47 calculates an equalization error by adding an output signal from the first adder 44 through the FF unit 42 and the FB unit 43, and a field synchronizing signal delayed for a predetermined delay time by the delay unit 49. Coefficients of the FIR filter of the FF unit 42 and the IIR filter of the FB unit 42 are updated using the equalization error calculated in each operation mode to remove multi-path of the received signal.

As described above, the coefficients of the filters are updated so as to converge on the levels of the multi-path signals for equalization of the equalizer. The coefficients of the filter are generally initialized as “1” for a center tap of the filter and “0” for others. The coefficients of the filter are updated by applying the equalization error calculated in response to each operation mode, thereby converging gradually.

Therefore, the equalizer has a problem in that coefficients of the filter converge in a long period of time and an equalization speed slows down.

### SUMMARY OF THE INVENTION

An aspect of the invention is to solve at least the above problems and/or disadvantages and to provide at least the advantages described hereinafter.

Accordingly, an aspect of the present invention is to solve the foregoing and/or other problems by providing a linear equalizer for a single carrier receiver, comprising: a channel estimation unit estimating channel estimation values using a received signal inputted thereto and a generated field synchronizing signal; a filter initializing coefficients of the filter based on the channel estimation values and filtering a pre-ghost and post-ghost of the received signal; and an error calculation unit calculating an equalization error using an output signal from said filter unit.

The linear equalizer may include a filter that updates the coefficients of the filters according to the equalization error and filters the pre-ghost and post-ghost using the updated coefficients of the filters.

The linear equalizer may have a channel estimation unit that includes: a correlation cumulation unit calculating and cumulating correlation values between the received signal and the field synchronizing signal; and an estimation decision unit deciding the channel estimation values by applying a predetermined threshold value to the cumulated correlation values.

The linear equalizer may further comprise a decision unit deciding a signal level for an output signal from said filter, wherein said error calculation unit calculates the equalization error using an input signal to said decision unit and an output signal from said decision unit.

The linear equalizer may include an error calculation unit that calculates the equalization error using the output signal from said decision unit and the field synchronizing signal.

The foregoing and/or other aspects and advantages are realized by providing an equalizing method of a linear equalizer, the method comprising: estimating a channel estimation value using a received signal and a field synchronizing signal; initializing coefficients of filters using the channel estimation value so as to remove a pre-ghost and post-ghost of the received signal; calculating an equalization error to update the coefficients of said filters; and updating the coefficients of said filters according to the equalization error, thereby filtering the pre and post-ghost.

According to the method, the estimating the channel estimation value may include: computing and cumulating correlation values by using a correlation between the received signal and the field synchronizing signal; and deciding the channel estimation value by applying a predetermined threshold value to the cumulated correlation values.

According to another aspect of the invention the foregoing and/or other aspects and advantages are realized by providing a decision feedback equalizer for a single carrier receiver, comprising: a channel estimation unit estimating a channel estimation value using a received signal inputted thereto and a generated field synchronizing signal; an FF unit initializing coefficients of a first filter based on the channel estimation value, and filtering a pre-ghost of the received signal; an FB unit initializing coefficients of a second filter based on the channel estimation value, and filtering a post-ghost of the received signal; and an error calculation unit calculating an equalization error using output signals from said FF and FB units.

The decision feedback equalizer may have FF and FB units that update the coefficients of the first and second filters, respectively, according to the equalization error and filter the pre and post-ghost using the updated first and second filters.

The decision feedback equalizer may have a channel estimation unit that includes: a correlation cumulation unit calculating and cumulating correlation values between the received signal and the field synchronizing signal; and an estimation decision unit deciding the channel estimation value by applying a predetermined threshold value to the cumulated correlation values.

The decision feedback equalizer may further comprise: an adder adding the output signals from said FF and FB units to output a resulting signal; a decision unit deciding a signal level for the output signal from said adder and inputting a resulting signal of the predetermined level to said FB unit, wherein said error calculation unit calculates an equalization error using the input signal to said decision unit and the output signal of the predetermined level from said decision unit.

The decision feedback equalizer may also further comprise: an adder adding the output signals from said FF and FB units to output a resulting signal, wherein said error calculation unit calculates the equalization error using the output signal from said adder and the field synchronizing signal.

According to yet another aspect of the invention the foregoing and/or other aspects and advantages are realized by providing a method an equalizing method of a decision feedback equalizer, the method comprising: estimating a channel estimation value using a received signal inputted thereto and a field synchronizing signal; initializing coefficients of a first and second filter to filter a pre and post-ghost, respectively, of the received signal using the channel estimation value; calculating an equalization error to update the coefficients of the first and second filter; and updating the coefficients of said first and second filter according to the equalization error, thereby filtering the pre and post-ghost.

According to the method, the estimating the channel estimation value may include: calculating and cumulating correlation values between the received signal and the field synchronizing signal; and an estimation decision unit deciding the channel estimation value by applying a predetermined threshold value to the cumulated correlation values.

Additional advantages, aspects, and features of the invention will be set forth in part in the description which follows and in part will become apparent to those having ordinary skill in the art upon examination of the following or may be learned from practice of the invention. The aspects and advantages of the invention may be realized and attained as particularly pointed out in the appended claims.

### BRIEF DESCRIPTION OF THE DRAWINGS

The invention will be described in detail with reference to the following drawings in which like reference numerals refer to like elements wherein:

FIG. 1 is a schematic block diagram of a conventional single carrier receiver;

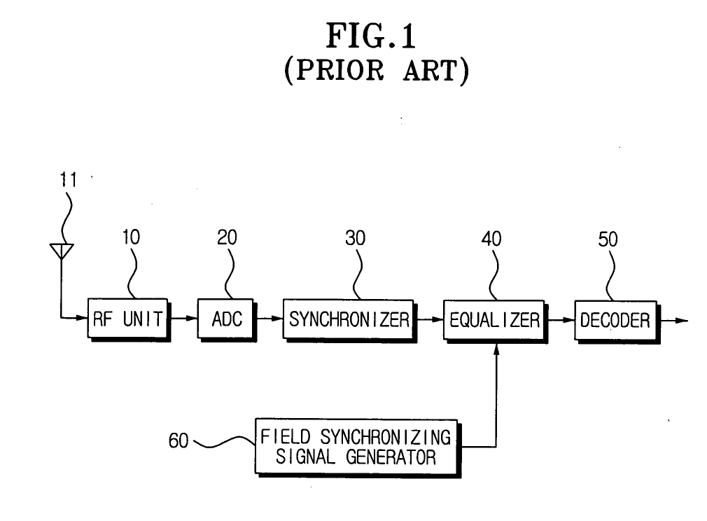

FIG. 2 is a block diagram of a linear equalizer for a single carrier receiver;

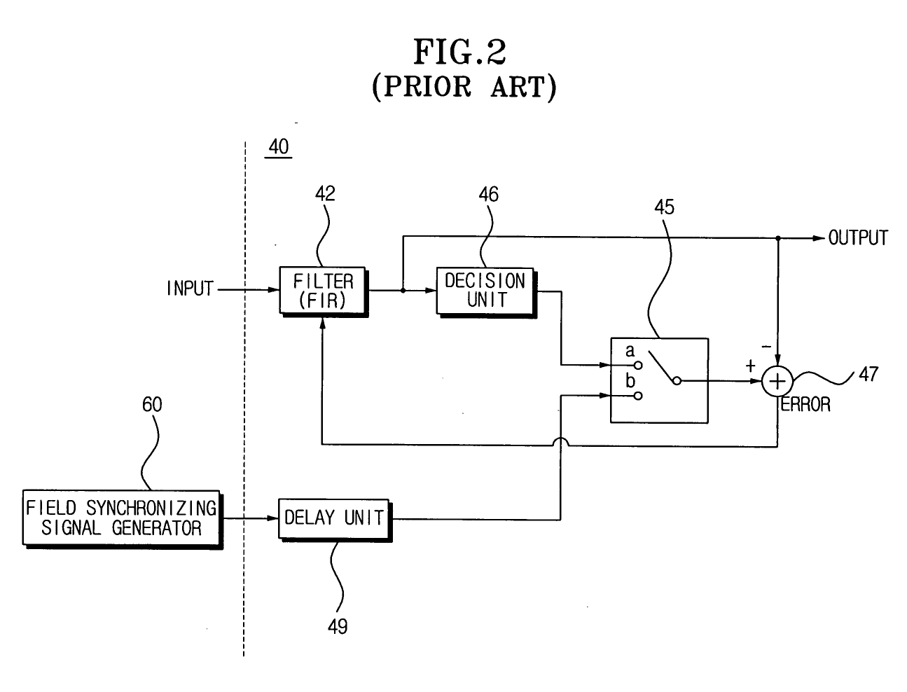

FIG. 3 is a block diagram of a decision feedback equalizer for a single carrier receiver;

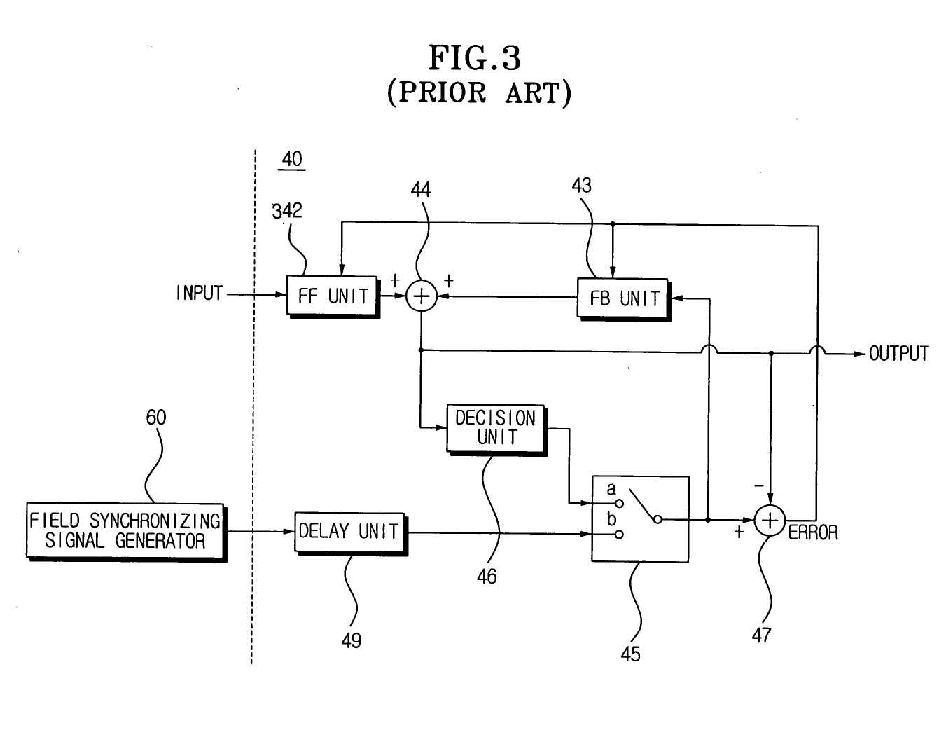

FIG. 4 is a block diagram of a linear equalizer in accordance with an embodiment of the present invention;

FIG. 5 is a block diagram of a decision feedback equalizer in accordance with an alternative embodiment of the present invention;

FIG. 6 is a detailed block diagram of a channel estimation unit in FIGS. 4 and 5;

FIG. 7 is a flow chart illustrating an equalizing method of the equalizers in FIGS. 4 and 5; and

FIG. 8 is a detailed flow chart illustrating the operation of channel estimation in FIG. 7.

### DETAILED DESCRIPTION OF PREFERRED EMBODIMENTS

Reference will now be made in detail to the present preferred embodiments of the present invention, examples of which are illustrated in the accompanying drawings, wherein like reference numerals refer to the like elements throughout. The embodiments are described below in order to explain the present invention by referring to the figures.

The following detailed description will present an equalizer for a single carrier receiver and an equaling method thereof according to embodiments of the invention in reference to the accompanying drawings.

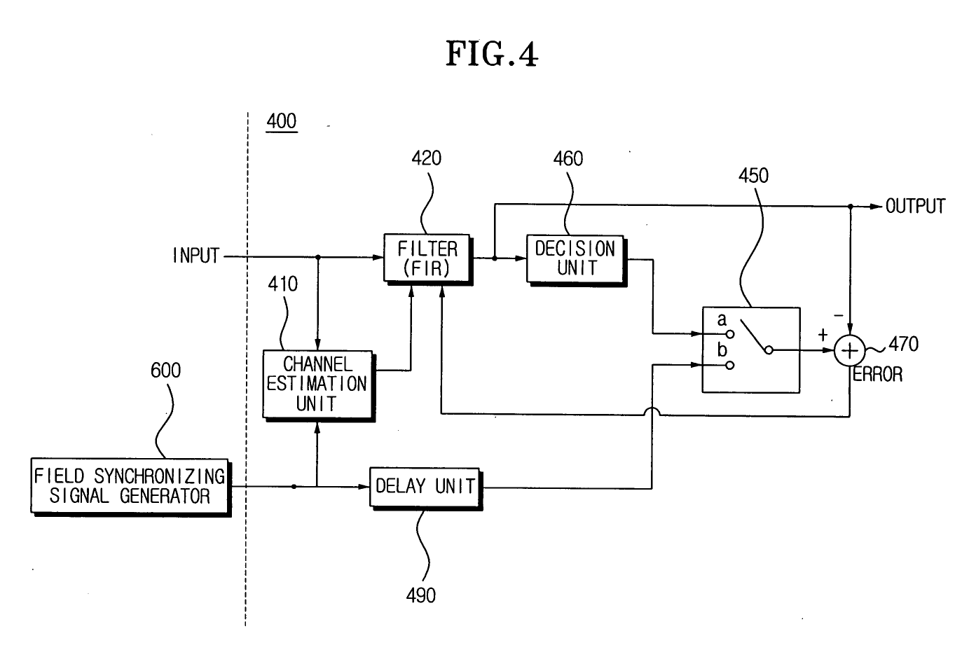

FIG. 4 is a block diagram of a linear equalizer in accordance with an embodiment of the present invention. The linear equalizer 400 comprises a channel estimation unit 410, a filter 420, a switching unit 450, a decision unit 460, an adder 470 and a delay unit 490.

The channel estimation unit 410 estimates a channel estimation value by using a correlation between a received signal inputted to a receiver and a field synchronizing signal, which is information synchronizing a transmitter and receiver, generated by a generator 600.

The filter 420 includes an FIR (finite impulse response) type filter. The filter 420 gradually attenuates levels of multi-path signals received before or after reception of a main signal to remove them.

The filter 420 initializes coefficients of the FIR filters using the channel estimation value from the channel estimation unit 410 and updates the coefficients of the filters according to an equalization error, which will be described later, to remove the multi-path signals of the received signal.

The switching unit 450 functions selectively in accordance with an operation mode, which is a blind or training mode, of the equalizer. The equalization error is computed in accordance with the operation mode.

The decision unit 460 decides a signal level for an output signal from the filter 420 when the equalizer is in the blind mode and outputs a resulting signal.

The delay unit 490 delays the field synchronizing signal for a predetermined period of time when the equalizer is in the training mode. The delay time is the same as a delay time of a main signal which is received with multi-path signals.

The adder 470 calculates an equalization error in response to each operation mode by adding the output signal from the filter 420 and the signal outputted from the switching unit 450 in response to the operation mode.

Hereinafter, an operation of the above linear equalizer will be described. The channel estimation unit 410 provides a channel estimation value according to a delay profile of a received signal to the filter 420. The filter 420 initializes coefficients of the FIR type filters according to the channel estimation value and filters the received signal. The adder 470 calculates an equalization error by using output signals from the filter 420 and the switching unit 450 which functions in accordance with each operation mode.

In the blind mode, the switching unit 450 is connected to a point a and the decision unit 460 decides a signal level for an output signal from the filter 420 to output to the adder 470. The adder 470 calculates an equalization error by adding the input signal to the decision unit 460 and the signal of the predetermined level outputted from the decision unit 460.

In the training mode the switching unit 450 is connected to a point b and the adder 470 calculates an equalization error by adding a field synchronizing signal and an output signal from the filter 420. The delay unit 490 delays the field synchronizing signal for a delay time of a main signal which is received with multi-path signals.

As described above, the coefficients of the FIR type filter of the filter 420 are updated by using the equalization error calculated in each operation mode. The coefficients of the filters have been made to converge on the levels of the multi-path signals to some degree by using the channel estimation value. Consequently, the coefficients of the filters are updated by using the equalization error so that they converge to perfection. This enables the coefficients of the filters to converge in a short period of time.

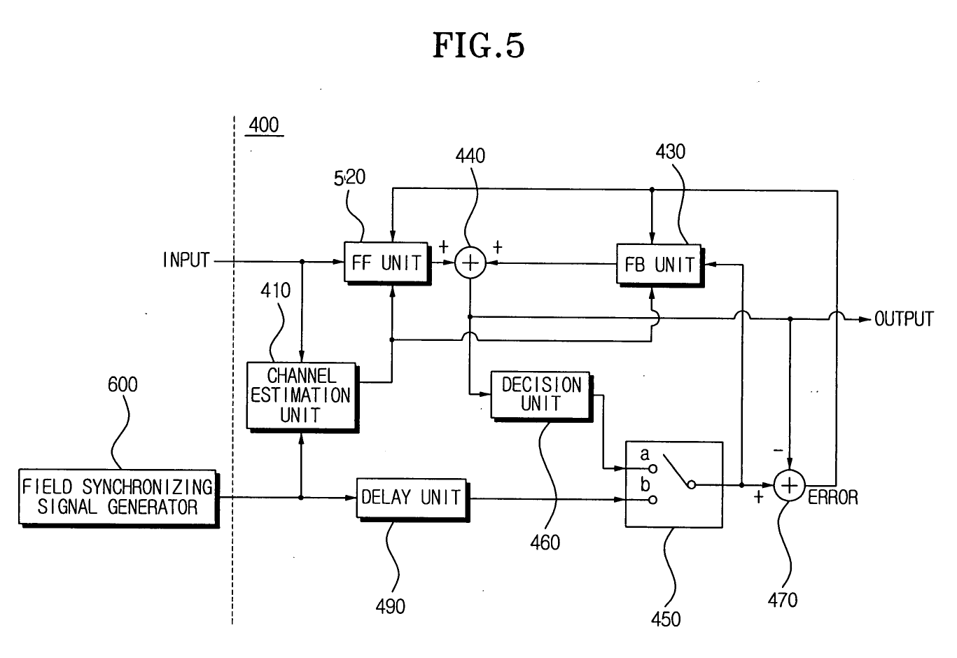

FIG. 5 is a block diagram of a decision feedback equalizer 400 in accordance with an alternative embodiment of the present invention.

The decision feedback equalizer 400 comprises a channel estimation unit 410, an FF (Feed Forward) unit 520, an FB (Feed Back) unit 430, a first adder 440, a switching unit 450, a decision unit 460, a second adder 470 and a delay unit 490.

The channel estimation unit 410 estimates a channel estimation value by using a correlation between a received signal inputted to a receiver and a field synchronizing signal, which is information synchronizing a transmitter and receiver, generated by a generator 600.

The FF unit 520 includes an FIR type filter to remove a pre-ghost, which is a multi-path signal received before reception of a main signal. Namely, the FF unit 520 initializes coefficients of the FIR filter to predetermined values by using the channel estimation value outputted from the channel estimation unit 410 and then updates the coefficients of the filters, thereby removing the pre-ghost.

The FB unit 430 includes an IIR (Infinite Impulse Response) type filter to remove a post-ghost, which is a multi-path signal received after reception of a main signal. Namely, the FB unit 430 initializes coefficients of the IIR filter to predetermined values by using a channel estimation value outputted from the channel estimation unit 410 and then updates the coefficients of the filters, thereby removing the post-ghost.

The first adder 440 adds output signals from the FF unit 520 and the FB unit 430.

The decision unit 460 decides a signal level for an output signal from the first adder 440 when the equalizer is in the blind mode.

The delay unit 490 delays the field synchronizing signal for a predetermined period of time when the equalizer is in the training mode. The delay time is the same as a delay time of a main signal which is received with multi-path signals.

The second adder 470 calculates an equalization error in response to each operation mode by adding the output signal from the first adder 440 and the signal outputted from the switching unit 450 in response to the operation mode.

Hereinafter, an operation of the above decision feedback equalizer will be described. The channel estimation unit 410 provides a channel estimation value according to a delay profile of a received signal to the FF unit 520 and the FB unit 430. The FF unit 520 and the FB unit 430 initiate coefficients of the FIR and the IIR filters based on the channel estimation value. The FF unit 520 and the FB unit 430 with the initialized coefficients of the filters filter the received signal. The second adder 470 calculates an equalization error by adding output signals from the first adder 440 and the switching unit 450.

In the blind mode, the switching unit 450 is connected to a point a so that the decision unit 460 decides a signal level for an output signal from the first adder 440. The second adder 470 calculates an equalization error by using input/output signals to/from the decision unit 460.

In the training mode the switching unit 450 is connected to a point b and the second adder 470 calculates an equalization error by using a field synchronizing signal and an output signal from the first adder 440. The delay unit 490 delays the field synchronizing signal for a delay time of a main signal which is received with multi-path signals.

As described above, the equalization error calculated in response to each operation mode is inputted to the FF unit 520 and the FB unit 430 so that the FF unit 520 and the FB unit 430 update the coefficients of filters corresponding to the input equalization error. The coefficients of the filters have been made to converge on the levels of the multi-path signals to some degree by using the channel estimation value and, consequently, are updated by using the equalization error so that they converge to perfection. This enables the coefficients of the filters to converge in a short period of time.

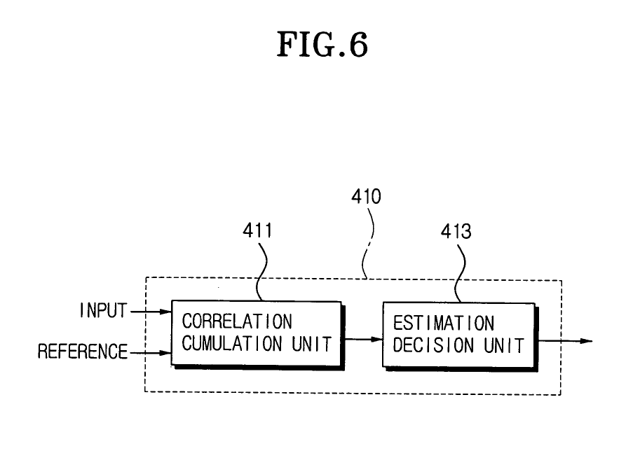

FIG. 6 is a detailed block diagram of the channel estimation unit 410. The channel estimation unit 410 includes a correlation cumulation unit 411 and an estimation decision unit 413.

The correlation cumulation unit 411 cumulates correlation values by using correlation between a field synchronizing signal and a received signal.

The estimation decision unit 413 removes unnecessary noises by applying an adaptive threshold algorithm or fixed threshold algorithm to the cumulated correlation values. A delay profile, or channel estimation value, of the received signal is then obtained.

The channel estimation value obtained as above is inputted to each of the FF unit 520 and the FB unit 430, thereby initializing the coefficients of the filters.

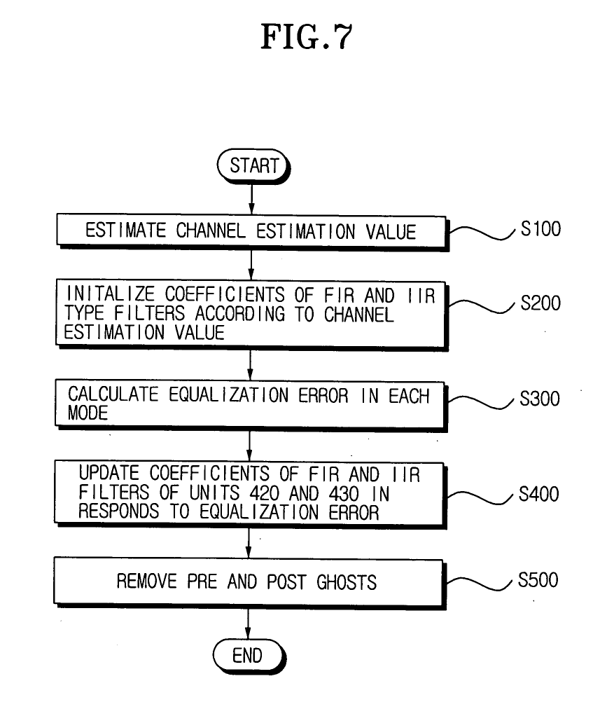

Hereinafter, an equalizing method of the equalizers according to the embodiments of the present invention (in FIGS. 4 and 5) will be described in detail in reference to a flow chart in FIG. 7.

The channel estimation unit 410 estimates a channel estimation value by using a correlation between a received signal inputted to the receiver and a field synchronizing signal generated from the generator 60 (S100).

The FF unit 520 and the FB unit 430 initialize coefficients of the FIR and IIR type filters, respectively, according to the channel estimation value (S200).

The switching unit 450 selectively functions in accordance with each operation mode to calculate an equalization error. In detail, an output signal from the decision unit 460 is used to calculate the equalization error in the blind mode and the field synchronizing signal is used to calculate the equalization error in the training mode (S300).

This equalization error calculated in response to each operation mode is inputted to the FF unit 520 and the FB unit 430. Then the FF unit 520 and the FB unit 430 update the coefficients of the FIR and IIR filters, respectively, in response to the input equalization error (S400).

The coefficients of the FIR and IIR filters are updated so as to converge to the levels of the pre and post-ghosts, thereby removing the pre and post-ghosts (S500).

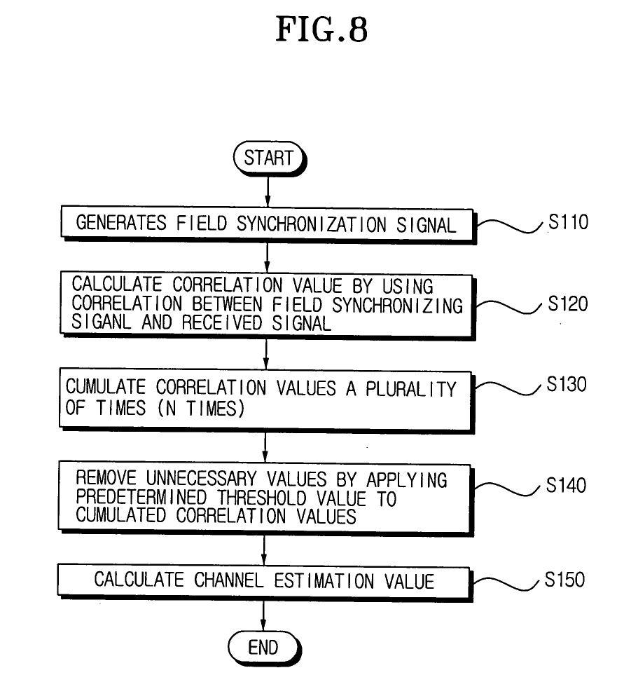

FIG. 8 is a detailed flow chart illustrating the operation of a channel estimation in FIG. 7. Hereinafter, the operation of the channel estimation will be described in detail.

The field synchronizing signal generator 600 generates a field synchronization signal (S110). The correlation cumulation unit 411 calculates a correlation value by using a correlation between the field synchronizing signal and a received signal (S120) and repeats this operation a plurality of times, say N times, to cumulate correlation values upon each synchronization value (S130). The estimation decision unit 413 removes unnecessary noises by applying an adaptive threshold algorithm or fixed threshold algorithm to the cumulated correlation values (S140) and calculates a channel estimation value (S150).

The FF unit 520 and the FB unit 430 initialize coefficients of their filters by using the channel estimation value from the channel estimation unit 410. The coefficients of the FIR and IIR filters of the filter units 420 and 430 are updated consecutively, thereby enabling the coefficients of the filters to converge in a short period of time.

According to the invention, convergence speed of coefficients of filters can be improved by estimating a delay profile of a received signal, thereby initializing an FIR filter and an IIR filter. This enables the coefficients of the filters to converge in a short period of time, thereby improving a convergence speed of equalization of an equalizer.

While the invention has been shown and described with reference to certain preferred embodiments thereof, it will be understood by those skilled in the art that various changes in form and details may be made therein without departing from the spirit and scope of the invention as defined by the appended claims.

The foregoing embodiments and advantages are merely exemplary and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A linear equalizer for a single carrier receiver, comprising:
a channel estimation unit estimating channel estimation values using a received signal inputted thereto and a generated field synchronizing signal;
a filter unit initializing coefficients of filters based on the channel estimation values and filtering a pre-ghost and a post-ghost of the received signal; and
an error calculation unit calculating an equalization error using an output signal from said filter unit.

2. The linear equalizer according to claim 1, wherein said filter unit updates the coefficients of the filters according to the equalization error and filters the pre-ghost and post-ghost using the updated coefficients of the filters.

3. The linear equalizer according to claim 1, wherein said channel estimation unit includes:
a correlation cumulation unit calculating and cumulating correlation values between the received signal and the field synchronizing signal; and
an estimation decision unit deciding the channel estimation values by applying a predetermined threshold value to the cumulated correlation values.

4. The linear equalizer according to claim 1, further comprising:
a decision unit deciding a signal level for an output signal from said filter unit, wherein said error calculation unit calculates the equalization error using an input signal to said decision unit and an output signal from said decision unit.

5. The linear equalizer according to claim 1, wherein said error calculation unit calculates the equalization error using the output signal from said decision unit and the field synchronizing signal.

6. An equalizing method of a linear equalizer, the method comprising:
estimating a channel estimation value using a received signal and a field synchronizing signal;
initializing coefficients of filters using the channel estimation value so as to remove a pre-ghost and post-ghost of the received signal;
calculating an equalization error to update the coefficients of said filters; and
updating the coefficients of said filters according to the equalization error, thereby filtering the pre-ghost and the post-ghost.

7. The method according to claim 6, wherein the estimating the channel estimation value comprises:
computing and cumulating correlation values by using a correlation between the received signal and the field synchronizing signal; and
deciding the channel estimation value by applying a predetermined threshold value to the cumulated correlation values.

8. A decision feedback equalizer for a single carrier receiver, comprising:
a channel estimation unit estimating a channel estimation value using a received signal inputted thereto and a generated field synchronizing signal;
a feed forward (FF) unit initializing coefficients of a first filter based on the channel estimation value, and filtering a pre-ghost of the received signal;
a feedback (FB) unit initializing coefficients of a second filter based on the channel estimation value, and filtering a post-ghost of the received signal; and
an error calculation unit calculating an equalization error using output signals from said FF and FB units.

9. The decision feedback equalizer according to claim 8, wherein said FF and FB units update the coefficients of the first and second filters, respectively, according to the equalization error and filter the pre-ghost and the post-ghost using the updated first and second filters.

10. The decision feedback equalizer according to claim 8, wherein said channel estimation unit comprises:
a correlation cumulation unit calculating and cumulating correlation values between the received signal and the field synchronizing signal; and
an estimation decision unit deciding the channel estimation value by applying a predetermined threshold value to the cumulated correlation values.

11. The decision feedback equalizer according to claim 8, further comprising:
an adder adding the output signals from said FF and FB units to output a resulting signal;
a decision unit deciding a signal level for the output signal from said adder and inputting the resulting signal of the predetermined level to said FB unit,
wherein said error calculation unit calculates an equalization error using the input signal to said decision unit and the output signal of the predetermined level from said decision unit.

12. The decision feedback equalizer according to claim 11, wherein said error calculation unit calculates the equalization error using the output signal from said adder and the field synchronizing signal.

13. An equalizing method of a decision feedback equalizer, the method comprising:
estimating a channel estimation value using a received signal inputted thereto and a field synchronizing signal;
initializing coefficients of a first filter and a second filter to filter a pre-ghost and a post-ghost, respectively, of the received signal using the channel estimation value;
calculating an equalization error to update the coefficients of the first and the second filter; and
updating the coefficients of said first filter and said second filter according to the equalization error, thereby filtering the pre-ghost and the post-ghost.

14. The method according to claim 13, wherein the estimating the channel estimation value includes:
calculating and cumulating correlation values between the received signal and the field synchronizing signal; and
an estimation decision unit deciding the channel estimation value by applying a predetermined threshold value to the cumulated correlation values.

15. A method of removing a multi-path signal from a received signal, comprising:
establishing a channel estimation value from a first signal and a second signal;
initializing filter coefficients to filter the multi-path signal based on the channel estimation value; and
updating the initialized filter coefficients according to an equalization error to remove the multi-path signal.

16. The method of claim 15, wherein the multi-path signal comprises:
a pre-ghost of the received signal; and
a post-ghost of the received signal.

17. The method of claim 15, wherein the estimating the channel estimation value comprises:
adding the first signal and the second signal.

18. The method of claim 15, further comprising:
determining if a blind mode is selected;
outputting a predetermined signal from a decision unit if the blind mode is selected; and
selecting the received signal as the first signal and the predetermined signal as the second signal when the blind mode is selected.

19. The method of claim 15, further comprising:
determining if a training mode is selected; and
selecting a field synchronizing signal as the first signal and an output signal from a filter having the updated filter coefficients as the second signal when the training mode is selected.

20. A method of removing multi-path signal levels from a received signal, comprising:
providing a channel estimation value according to a delay profile of the received signal;
converging filter coefficients on the multi-path signal levels using the channel estimation value and an equalization error.

21. The method of claim 20, wherein the converging the filter coefficients comprises:
initializing the filter coefficients with the channel estimation value.

22. The method of claim 20, wherein the converging the filter coefficients comprises:
updating the filter coefficients with the equalization error.

23. The method of claim 20, wherein the converging the filter coefficients comprises:
converging the filter coefficients having a finite impulse response.

24. The method of claim 20, wherein the converging the filter coefficients comprises:
converging the filter coefficients having an infinite impulse response.
